(19) United States
(12) Patent Application Publication
(10) Pub. No.: US 2013/0215722 A1
(43) Pub. Date: Aug. 22, 2013

(54) ULTRASONIC SENSOR DEVICES, COMPONENT MODULE THEREOF AND METHOD FOR MAKING THE ULTRASONIC SENSOR DEVICE

(71) Applicants: Wen-Jong Wu, Taipei (TW); Chuin-Shan Chen, Taipei (TW); Nai-Chang Wu, Taipei (TW); Chia-Yu Lin, Taoyuan County (TW); Tzu-Chin Tsai, Taoyuan County (TW); Chiun-Hua Chang, Taoyuan County (TW); Shih-Feng Lee, Taoyuan County (TW)

(72) Inventors: Wen-Jong Wu, Taipei (TW); Chuin-Shan Chen, Taipei (TW); Nai-Chang Wu, Taipei (TW); Chia-Yu Lin, Taoyuan County (TW); Tzu-Chin Tsai, Taoyuan County (TW); Chiun-Hua Chang, Taoyuan County (TW); Shih-Feng Lee, Taoyuan County (TW)

(21) Appl. No.: 13/554,961

(22) Filed: Jul. 20, 2012

(30) Foreign Application Priority Data
Feb. 21, 2012 (TW) 101105663

(51) Int. Cl. H04R 17/00; H05K 3/30

(52) U.S. Cl. 367/188; 29/832

(57) ABSTRACT

An ultrasonic sensor device includes a sensing unit and a component module disposed in a casing. The sensing unit is configured to generate a sensing signal in response to receipt of an external sound wave. The component module includes a base seat, a circuit unit and a cushioning unit. The base seat has a base board and a lower seat portion under the base board. The base board is formed with a recess. The circuit unit is disposed in the recess, is coupled electrically to the sensing unit for receiving the sensing signal therefrom, and is to be coupled electrically to an external electronic circuit. The cushioning unit is disposed at the base seat, and is proximate to the sensing unit.

### CROSS-REFERENCE TO RELATED APPLICATION

This application claims priority of Taiwanese Application No. 101105663, filed on Feb. 21, 2012.

### BACKGROUND OF THE INVENTION

1. Field of the Invention

The invention relates to a sensor device, more particularly to an ultrasonic sensor device.

2. Description of the Related Art

An ultrasonic sensor is generally for detecting objects by transceiving ultrasonic waves. In U.S. Pat. No. 5,987,992, there is disclosed a conventional ultrasonic sensor that comprises a casing, a piezoelectric vibration member, a sound absorbing member, a pair of electrodes, and an elastic resin.

However, the aforementioned ultrasonic sensor has some drawbacks. For example, sizes of the components and space inside the casing for such ultrasonic sensor are typically small. As a result, it may be difficult to assemble the ultrasonic sensor. Moreover, in a conventional manufacturing process of the ultrasonic sensor, components are separately mounted in the casing by adhesive. Such procedure may be time consuming since a drying step must be executed each time a component is adhered to the casing.

### SUMMARY OF THE INVENTION

Therefore, an object of the present invention is to provide an ultrasonic sensor device that utilizes a component module for simplifying the manufacturing process, and for reducing the time for completing the manufacturing process.

Accordingly, an ultrasonic sensor device of the present invention is adapted for coupling to an external electronic circuit. The ultrasonic sensor device comprises a casing, a sensing unit, and a component module.

The casing has a bottom wall and a surrounding wall extending upwardly from a periphery of the surrounding wall. The bottom wall and the surrounding wall cooperate to define a containing space.

The sensing unit is disposed on top of the bottom wall and is configured to generate a sensing signal in response to receipt of an external sound wave.

The component module is disposed in the containing space of the casing. The component module includes a base seat, a circuit unit and a cushion unit.

The base seat has at least one external surface formed from a flexible material. The base seat further has a base board and a lower seat portion under the base board. The base board has a top face that is opposite to the sensing unit and that is formed with a recess.

The circuit unit is disposed in the recess, and coupled electrically to the sensing unit for receiving the sensing signal therefrom. The circuit unit is adapted for coupling electrically to the external electronic circuit.

The cushioning unit is disposed at the lower seat portion of the base seat and is disposed proximate to the sensing unit. The cushioning unit is formed from a material capable of absorbing shockwaves.

Another object of the present invention is to provide a component module that simplifies the assembling process.

Accordingly, a component module for an ultrasonic sensor device is disclosed. The ultrasonic sensor device includes a casing and a sensing unit disposed in the casing. The component module comprises a base seat, circuit unit and a cushion unit.

The base seat is configured to be disposed in the casing and has at least one external surface that is formed from a flexible material. The base seat has a base board and a lower seat portion under the base board. The base board has a top face that is to be disposed opposite to the sensing unit in the casing and that is formed with a recess.

The circuit unit is disposed in the recess and is to be coupled electrically to the sensing unit.

The cushioning unit is disposed at the lower seat portion of the base seat, is to be disposed proximate to the sensing unit in the casing, and is formed from a material capable of absorbing shockwaves.

Still another object of the present invention is to provide a method for making the aforementioned ultrasonic sensor device.

Accordingly, a method for making an ultrasonic sensor device of this invention comprises the following steps of:

mounting a circuit unit and a cushioning unit on a base seat to form a component module, wherein the base seat includes a base board formed with a recess and a lower seat portion under the base board, the circuit unit being mounted in the recess, the cushioning unit being mounted to the lower seat portion and being formed from a material capable of absorbing shockwaves;

mounting a sensing unit that is responsive to sound waves in a casing, and connecting one end of an electrical conductor to the sensing unit;

disposing the component module in the casing; and connecting the other end of the electrical conductor to the circuit unit.

### BRIEF DESCRIPTION OF THE DRAWINGS

Other features and advantages of the present invention will become apparent in the following detailed description of the preferred embodiment with reference to the accompanying drawings, of which:

FIG. 1 is an exploded perspective view of a preferred embodiment of an ultrasonic sensor device according to the invention;

FIG. 2 is an assembled perspective view of the embodiment;

FIG. 3 is a top view of the embodiment;

FIG. 4 is a side sectional view taken along line IV-IV of FIG. 3;

FIG. 5 is an assembled perspective view illustrating an implementation of a component module;

FIG. 6 is an exploded perspective view of the component module;

FIG. 7 is a side sectional view taken along line VII-VII of FIG. 5;

FIG. 8 is a flow chart illustrating a preferred embodiment of a method for making the ultrasonic sensor device according to the invention;

FIG. 9 is a schematic view illustrating a sensing unit, a first electrical conductor and a second electrical conductor being assembled to a casing;

FIG. 10 is a schematic view illustrating the component module being disposed in the casing; and

FIG. 11 is a schematic view illustrating a connecting wire unit being connected to a circuit unit.

### DETAILED DESCRIPTION OF THE PREFERRED EMBODIMENT

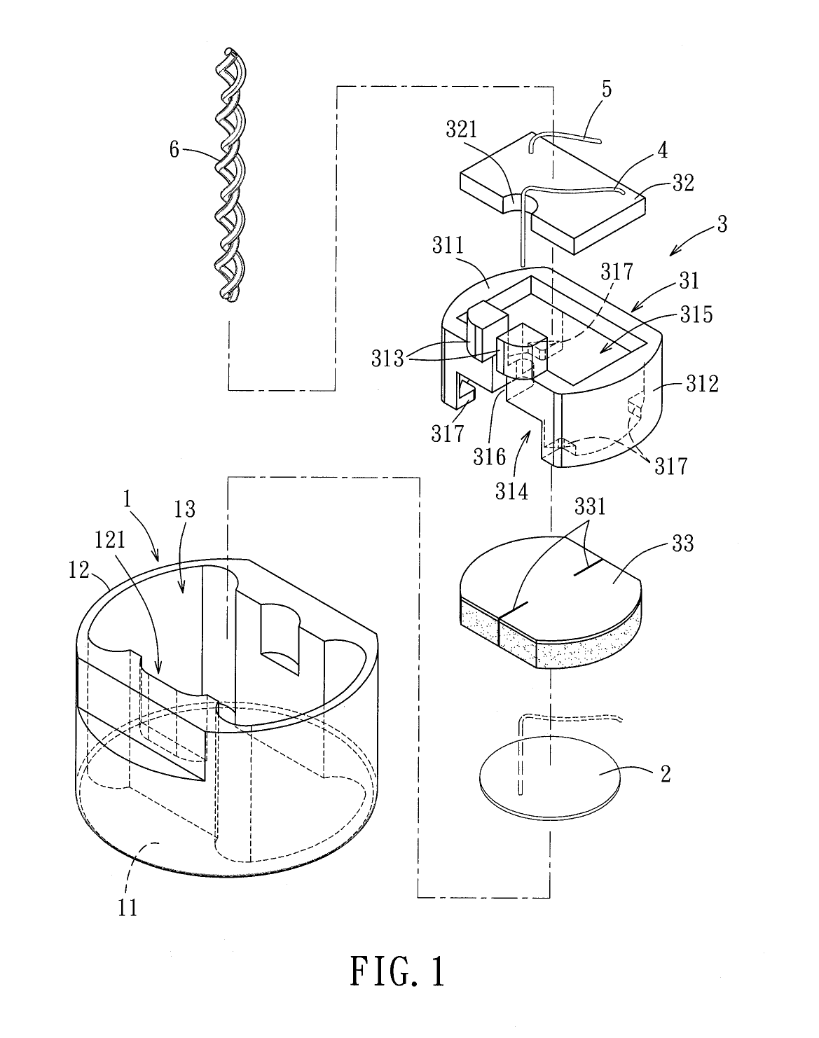

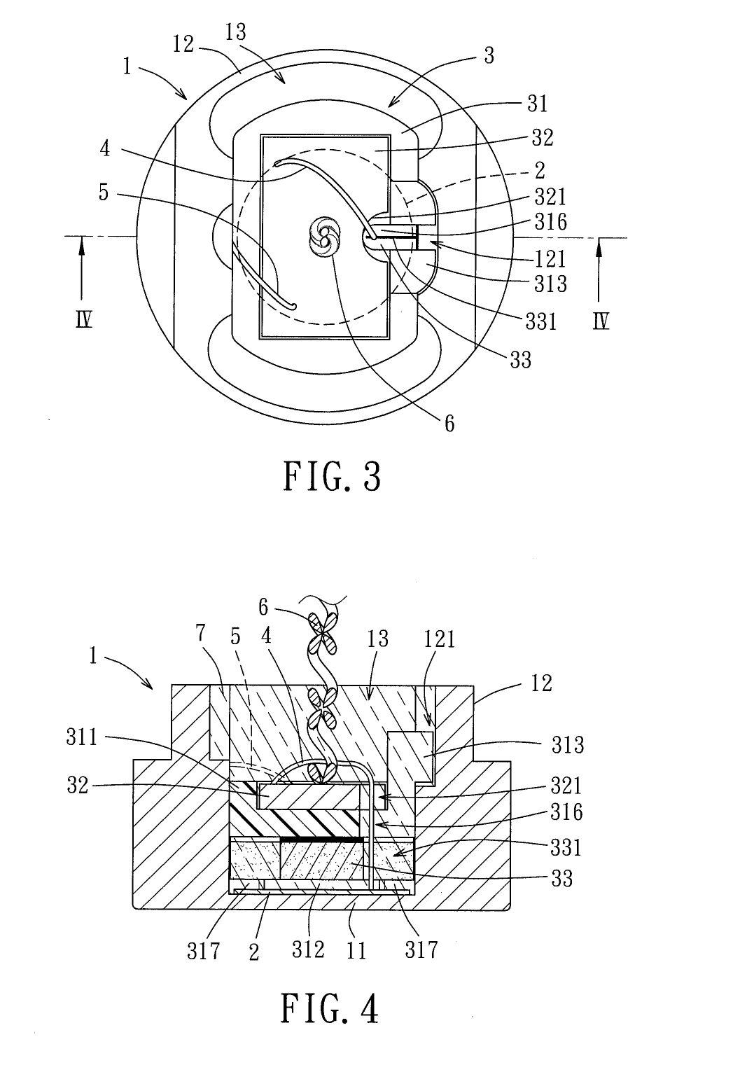

As shown in FIGS. 1 to 4, the preferred embodiment of an ultrasonic sensor device according to the present invention is for detecting distance with an object, and can be installed in a vehicle. The ultrasonic sensor device is adapted for coupling to an external electronic circuit (not shown) for processing signals. The ultrasonic sensor device comprises a casing 1, a sensing unit 2, a component module 3, a first electrical conductor 4, a second electrical conductor 5, a connecting wire unit 6, and a sealing component 7. In this embodiment, each of the first and second electrical conductors 4 and 5 is a piece of conducting wire.

The casing 1 is formed from an electrically conductive material (e.g., a metal such as aluminum) and is substantially in the shape of a cylinder. The casing 1 includes a bottom wall 11 and a surrounding wall 12 that extends upwardly from a periphery of the bottom wall 11. The bottom wall 11 and the surrounding wall 12 cooperate to define a containing space 13. The surrounding wall 12 has an inner surface formed with a first positioning member 121. In this embodiment, the first positioning member 121 is a positioning groove.

The sensing unit 2 is substantially circular in shape and is disposed on top of the bottom wall 11. In this embodiment, the sensing unit 2 is made of a piezoelectric material, and is operable in a conventional manner to generate a sensing signal in response to receipt of an external sound wave.

The component module 3 is disposed in the containing space 13 of the casing 1, and includes a base seat 31, a circuit unit 32 and a cushioning unit 33.

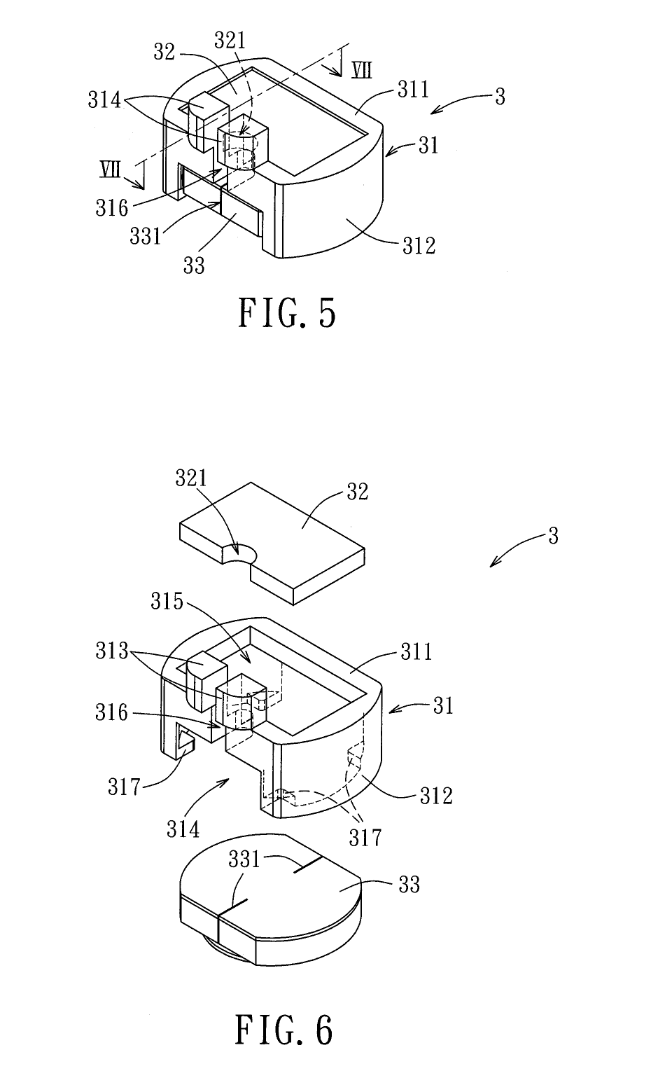

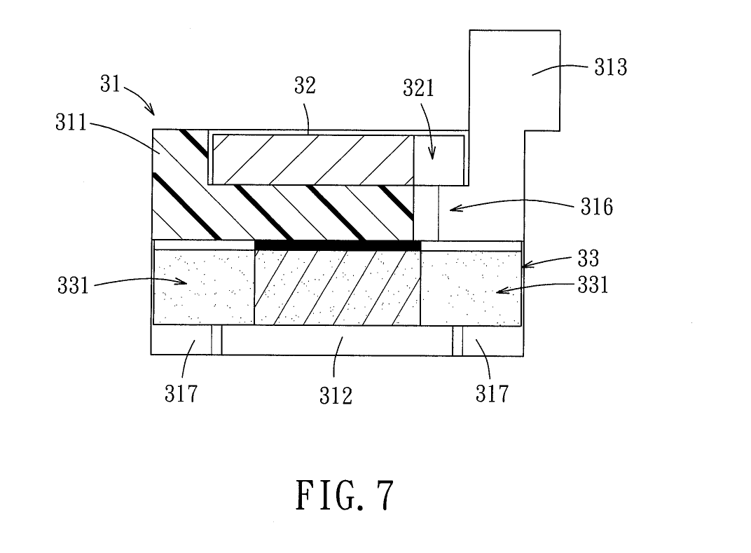

As shown in FIGS. 5 to 7, the base seat 31 is made from a flexible material (such as silicon), and has a base board 311, and a lower seat portion that is under the base board 311 and that includes a pair of side walls 312 extending downwardly and respectively from opposite sides of the base board 311. The base board 311 has a top face opposite to the sensing unit 2 and formed with a recess 315. The base board 311 is further formed with a pair of second positioning members 313, and a conductor passage 316. In this embodiment, each of the second positioning members 313 is a positioning block, and the conductor passage 316 is a notch formed in a periphery of the base board 311. A limiting component 317 is formed on each of front and rear ends of each of the side walls 312 and is vertically spaced apart from the base board 311. The base board 311, the side walls 312 and the limiting components 317 cooperate to define a receiving space 314 for receiving the cushioning unit 33 therein.

The circuit unit 32 is substantially rectangular in shape (see FIG. 4), is received in the recess 315, and is formed with an indentation 321. The circuit unit 32 is electrically coupled to the sensing unit 2 through the first electrical conductor 4 for receiving the sensing signal therefrom, and is electrically coupled to the external electronic circuit through the connecting wire unit 6.

The cushioning unit 33 is formed from a material capable of absorbing shockwaves (e.g., foam or cotton), and is disposed at the lower seat portion of the base seat 31 proximate to the sensing unit 2. In particular, the cushioning unit 33 is received in the receiving space 314 and is supported by the limiting components 317. The cushioning unit 33 is formed with slots 331, one of which is registered with the conductor passage 316 and the indentation 321.

As shown in FIGS. 1, 2 and 4, the first electrical conductor 4 extends through the conductor passage 316 and the slot 331 for interconnecting electrically the circuit unit 32 and the sensing unit 2. The second electrical conductor 5 interconnects the circuit unit 32 and an inner wall surface of the surrounding wall 12 of the casing 1 in order to form a ground connection. The connecting wire unit 6 includes a twisted pair for transmitting the sensing signal received from the circuit unit 32 to the external electronic circuit.

The sealing component 7 is also formed from a material that is capable of absorbing shockwaves (e.g., silicone rubber), and is configured to fill the casing 1 to encapsulate the component module 3, the sensing unit 2, the first and second electrical conductors 4 and 5, and a part of the connecting wire unit 6.

In such configuration, the external electronic circuit is operable to transmit an actuation signal which is transmitted to the sensing unit 2 through the connecting wire unit 6, the circuit unit 32 and the first electrical conductor 4. Upon receipt of the actuation signal, the sensing unit 2 is operable to generate an ultrasonic signal that propagates outwardly so as to be reflected by an object. The reflected ultrasonic signal is then received by the sensing unit 2 which in turn generates the sensing signal. The sensing signal is subsequently transmitted back to the external electronic circuit through the first electrical conductor 4, the circuit unit 32 and the connecting wire unit 6, and the external electronic circuit is operable to process the sensing signal. Since processing of the sensing signal by the external electronic circuit is not a feature of the present invention, details thereof are omitted herein for the sake of brevity.

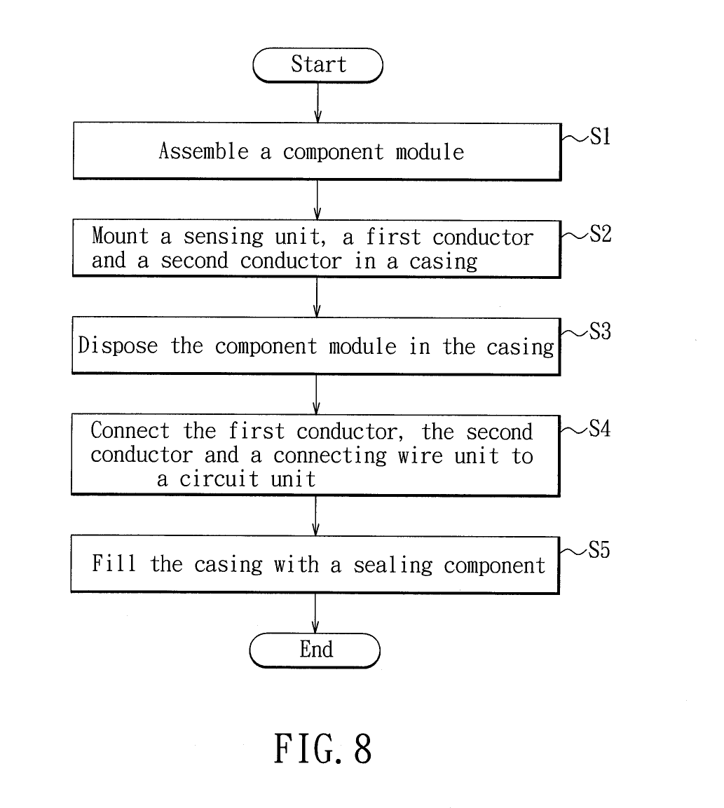

Referring to FIG. 8, steps of a method for making the aforementioned ultrasonic sensor device will now be described in detail.

In step S1, the component module is 3 assembled. Specifically, the circuit unit 32 is mounted in the recess 315 of the base board 311 by adhesive, and the cushioning unit 33 is disposed in the receiving space 314 and mounted to a bottom side of the base board 311 by adhesive (see FIG. 6).

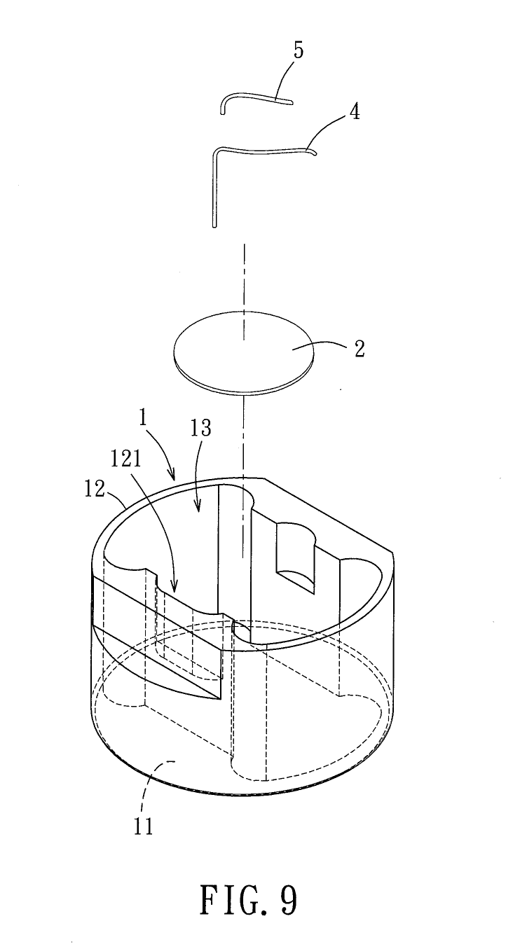

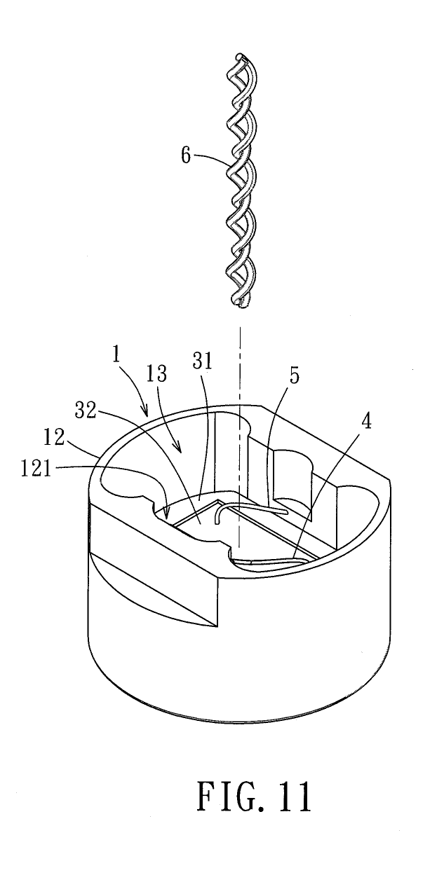

In step S2, the sensing unit 2, the first electrical conductor 4, and the second electrical conductor 5 are mounted in the casing 1. Specifically, the sensing unit 2 is mounted on top of the bottom wall 11, one end of the first electrical conductor 4 is connected to the sensing unit 2, and one end of the second electrical conductor 5 is connected to an inner surface of the casing 1 (see FIGS. 9 and 11).

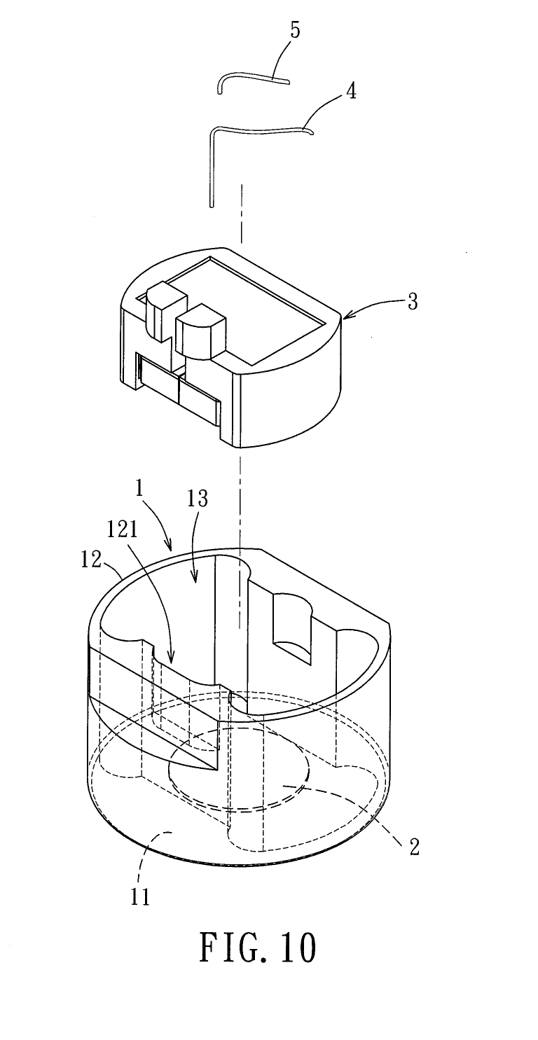

In step S3, the component module 3 is disposed in the casing 1. Specifically, the second positioning members 313 engage the first positioning member 121, and the cushioning unit 33 is disposed on top of the sensing unit 2 (see FIG. 10).

In step S4, the first electrical conductor 4, the second electrical conductor 5 and the connecting wire unit 6 are connected to the circuit unit 32. Specifically, the other end of the first electrical conductor 4 is extended through the conductor passage 316 and the slot 331, and is connected to the circuit unit 32 via soldering. The other end of the second electrical conductor 5 is connected to the circuit unit 32 via soldering and is spaced apart from the first electrical conductor 4. One end of the connecting wire unit 6 is connected to a central position on top of the circuit unit 32 (see FIG. 11).

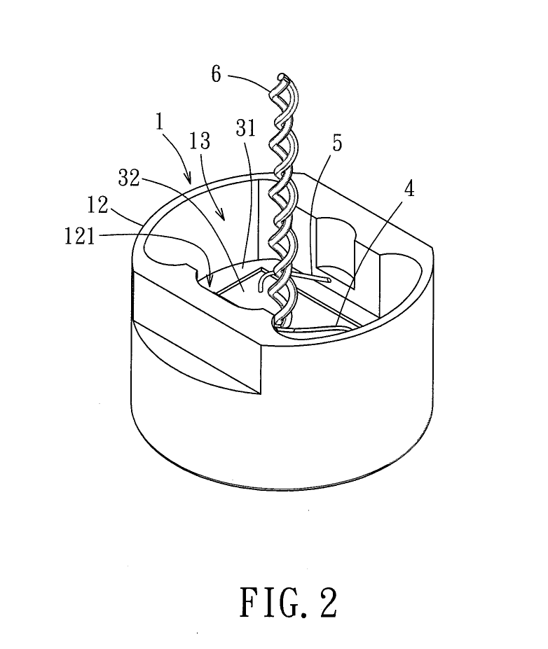

Finally, in step S5, the containing space 13 of the casing 1 is filled with the sealing component 7 (see FIGS. 2 and 4).

To sum up, the configuration of the component module 3 allows a part of the manufacturing procedure of the ultrasonic sensor device of this invention to be done outside the casing 1, thereby reducing the difficulty of the manufacturing procedure. Moreover, numerous drying steps in the conventional procedure can be omitted, making the manufacturing procedure of the present invention relatively less time-consuming.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. An ultrasonic sensor device adapted for coupling to an external electronic circuit, said ultrasonic sensor device comprising:
a casing having a bottom wall and a surrounding wall extending upwardly from a periphery of said surrounding wall, said bottom wall and said surrounding wall cooperating to define a containing space;
a sensing unit disposed on top of said bottom wall and configured to generate a sensing signal in response to receipt of an external sound wave; and
a component module disposed in said containing space of said casing, said component module including
a base seat that has at least one external surface formed from a flexible material, said base seat having a base board and a lower seat portion under said base board, said base board having a top face opposite to said sensing unit and formed with a recess,
a circuit unit disposed in said recess, coupled electrically to said sensing unit for receiving the sensing signal therefrom, and adapted for coupling electrically to the external electronic circuit, and
a cushioning unit disposed at said lower seat portion of said base seat, disposed proximate to said sensing unit, and formed from a material capable of absorbing shockwaves.

2. The ultrasonic sensor device as claimed in claim 1, wherein said surrounding wall has an inner surface formed with a first positioning member, and said base board of said base seat is formed with a second positioning member for engaging said first positioning member, one of said first and second positioning members being a positioning groove, the other of said first and second positioning members being a positioning block.

3. The ultrasonic sensor device as claimed in claim 1, wherein said base board is formed with a conductor passage, and said cushioning unit is formed with a slot that is registered with said conductor passage, said ultrasonic sensor device further comprising an electrical conductor configured to extend through said conductor passage and said slot, and to interconnect electrically said circuit unit and said sensing unit.

4. The ultrasonic sensor device as claimed in claim 3, wherein said base board has a periphery formed with a notch that serves as said conductor passage.

5. The ultrasonic sensor device as claimed in claim 1, wherein said casing is formed from an electrically conductive material, said ultrasonic sensor device further comprising an electrical conductor disposed to interconnect electrically said circuit unit and said casing, and a connecting wire unit connected electrically to said circuit unit and to be connected to the external electronic circuit.

6. The ultrasonic sensor device as claimed in claim 1, further comprising a sealing component configured to fill said containing space and to encapsulate said sensing unit and said component module.

7. The ultrasonic sensor device as claimed in claim 1, wherein
said lower seat portion of said base seat includes a pair of side walls extending downwardly and respectively from opposite sides of said base board, and at least one limiting component formed on one of said side walls and vertically spaced apart from said base board, and
said base board, said side walls and said limiting component cooperate to define a receiving space for receiving said cushioning unit therein.

8. A component module for an ultrasonic sensor device, the ultrasonic sensor device including a casing and a sensing unit disposed in the casing, said component module comprising:
a base seat that is configured to be disposed in the casing and that has at least one external surface formed from a flexible material, said base seat having a base board and a lower seat portion under said base board, said base board having a top face to be disposed opposite to the sensing unit in the casing and formed with a recess;
a circuit unit disposed in said recess and to be coupled electrically to the sensing unit; and
a cushioning unit disposed at said lower seat portion of said base seat, to be disposed proximate to the sensing unit in the casing, and formed from a material capable of absorbing shockwaves.

9. The component module as claimed in claim 8, wherein said surrounding wall has an inner surface formed with a first positioning member, and said base board of said base seat is formed with a second positioning member for engaging said first positioning member, one of said first and second positioning members being a positioning groove, the other of said first and second positioning members being a positioning block.

10. The component module as claimed in claim 8, wherein said base board is formed with a conductor passage, and said cushioning unit is formed with a slot that is registered with said conductor passage.

11. The component module as claimed in claim 10, wherein said base board has a periphery formed with a notch that serves as said conductor passage.

12. The component module as claimed in claim 8, wherein
said lower seat portion of said base seat includes a pair of side walls extending downwardly and respectively from opposite sides of said base board, and at least one limiting component formed on one of said side walls and vertically spaced apart from said base board, and
said base board, said side walls and said limiting component cooperate to define a receiving space for receiving said cushioning unit therein.

13. A method for making an ultrasonic sensor device, comprising the following steps of:
(a) mounting a circuit unit and a cushioning unit on a base seat to form a component module, wherein the base seat includes a base board formed with a recess and a lower seat portion under the baseboard, the circuit unit being mounted in the recess, the cushioning unit being mounted to the lower seat portion and being formed from a material capable of absorbing shockwaves;
(b) mounting a sensing unit that is responsive to sound waves in a casing, and connecting one end of a first electrical conductor to the sensing unit;
(c) disposing the component module in the casing; and
(d) connecting the other end of the first electrical conductor to the circuit unit.

14. The method as claimed in claim 13, wherein the casing has an inner surface formed with a first positioning member, and the base seat is formed with a second positioning member for engaging the first positioning member, one of the first and second positioning members being a positioning groove, the other of the first and second positioning members being a positioning block.

15. The method as claimed in claim 13, wherein the base board is formed with a conductor passage, and the cushioning unit is formed with a slot that is registered with the conductor passage, the first electrical conductor being configured to extend through the conductor passage and the slot.

16. The method as claimed in claim 13, further comprising the steps of:
connecting one end of a second electrical conductor to the casing and the other end of the second electrical conductor to the circuit unit; and
connecting one end of a connecting wire unit to the circuit unit.

17. The method as claimed in claim 13, further comprising the step of:
filling the casing with a sealing component to encapsulate the component module, the sensing unit and the first electrical conductor.

18. The method as claimed in claim 13, wherein
the lower seat portion of the base seat includes a pair of side walls extending downwardly and respectively from opposite sides of the base board, and at least one limiting component formed on one of the side walls and vertically spaced apart from the base board, and
the base board, the side walls and the limiting component cooperate to define a receiving space for receiving the cushioning unit therein.
